(19) United States
(12) Patent Application Publication
(10) Pub. No.: US 2021/0384202 A1
(43) Pub. Date: Dec. 9, 2021

(54) SEMICONDUCTOR STRUCTURE AND METHOD OF FORMING THE SAME

(71) Applicant: NANYA TECHNOLOGY CORPORATION, New Taipei City (TW)

(72) Inventors: Ting-Cih KANG, New Taipei City (TW); Chen CHU, Taoyuan City (TW); Chin-Ling HUANG, Taoyuan City (TW); Hsih-Yang CHIU, Taoyuan City (TW)

(21) Appl. No.: 16/892,297

(22) Filed: Jun. 4, 2020

(51) Int. Cl. H01L 27/112; H01L 21/762; H01L 21/8234; H01L 21/265

(52) U.S. Cl. CPC H01L 27/11206; H01L 21/76224; H01L 21/823481; H01L 21/26513; H01L 21/823437

(57) ABSTRACT

A semiconductor structure includes a substrate, a shallow trench isolation (STI) structure, a first gate structure, a second gate structure, a first contact, and a second gate contact. The substrate has an active region. The STI structure is disposed in the substrate and adjacent to the active region. The first gate structure and the second gate structure is disposed on the active region, wherein a vertical projection region of the first gate structure on the substrate and a vertical projection region of the second gate structure on the substrate are spaced apart from the STI structure. The first contact and the second contact are respectively disposed on the first gate structure and the second gate structure.

### BACKGROUND

### Technical Field

The present disclosure relates to a semiconductor structure and a method of forming the semiconductor structure.

### Description of Related Art

Semiconductor memory devices may be classified into two categories, volatile memory devices and nonvolatile memory devices. The volatile memory devices that have the information stored in a particular storage element, and the information is lost instantly when the power is removed from a circuit. In contrast to the volatile memory devices, the information of the nonvolatile memory devices is preserved even with the power removed. In regards to the nonvolatile memory devices, some designs allow multiple programming, while other designs allow one-time programming. Typically, the manufacturing techniques used to form nonvolatile memory devices are quite different from a standard logic process, which dramatically increases the complexity and chip size.

Conventional program (PM) of microcontrollers has generally been implemented by using non-volatile memories. For example, a complementary metal-oxide structure (CMOS) includes a gate oxide and a gate structure, in which the gate oxide of the CMOS has the great advantage of its feasibility to be applied to standard CMOS direct with no additional processes. Therefore, CMOS gate oxide anti-fuse (AF) is a promising candidate to be integrated as the PM of microcontrollers. However, the corner rounding effect occurs on the interface of the gate structure, the active region, and the isolation structure and adversely affects the stability and the performance of the semiconductor memory devices.

### SUMMARY

One aspect of the present disclosure is a semiconductor structure.

According to some embodiments of the present disclosure, a semiconductor structure includes a substrate, a shallow trench isolation (STI) structure, a first gate structure, a second gate structure, a first contact, and a second gate contact. The substrate has an active region. The STI structure is disposed in the substrate and adjacent to the active region. The first gate structure and the second gate structure is disposed on the active region, wherein a vertical projection region of the first gate structure on the substrate and a vertical projection region of the second gate structure on the substrate are spaced apart from the STI structure. The first contact and the second contact are respectively disposed on the first gate structure and the second gate structure.

In some embodiments, the semiconductor structure further includes a third contact on the active region.

In some embodiments, the semiconductor structure further includes an electrode plate on the third contact.

In some embodiments, a top surface of the first contact, a top surface of a second contact, and a top surface of the third contact are at same horizontal level.

In some embodiments, a bottom surface of the first contact and a bottom surface of a second contact are higher than a bottom surface of the third contact.

In some embodiments, the first contact, the second contact, and third contact are made of same materials.

In some embodiments, the semiconductor structure further includes an electrode plate extending from the first contact to the second contact.

In some embodiments, the semiconductor structure further includes a first gate dielectric layer and a second gate dielectric layer. The first gate dielectric layer is disposed between the first gate structure and the active region. The second gate dielectric layer is disposed between the second gate structure and the active region.

In some embodiments, the first gate dielectric layer and second gate dielectric layer are spaced apart from the STI structure.

In some embodiments, the active region includes N-type dopants.

Another aspect of the present disclosure is a method of forming a semiconductor structure.

According to some embodiments of the present disclosure, a method of forming a semiconductor structure includes following steps. A shallow trench isolation (STI) structure is formed in a substrate. An active region is formed adjacent to the STI structure. A first gate structure and a second gate structure is formed on the active region such that a vertical projection region of the first gate structure on the substrate and a vertical projection region of the second gate structure on the substrate are spaced apart from the STI structure. A first contact and a second contact are respectively formed on the first gate structure and the second gate structure.

In some embodiments, forming the active region includes performing an implant process on the substrate.

In some embodiments, the method of forming the semiconductor structure further includes forming a third contact on the active region after forming the first gate structure and the second gate structure on the active region.

In some embodiments, forming the first contact and the second contact respectively on the first gate structure and the second gate structure and forming the third contact on the active region are performed by using one deposition process.

In some embodiments, the method of forming the semiconductor structure further includes forming an electrode plate on the third contact.

In some embodiments, the method of forming the semiconductor structure further includes forming an electrode plate that extends from the first contact to the second contact.

In the aforementioned embodiments, since the vertical projection region of the first gate structure on the substrate and the vertical projection region of the second gate structure on the substrate are spaced apart from the STI structure, corner rounding effect can be avoided. As a result, the stability and the performance of the semiconductor structure can be improved.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a top view of a layout of a semiconductor structure in accordance with one embodiment of the present disclosure;

FIG. 2 is a cross-sectional view of the semiconductor structure taken along line 2-2 of FIG. 1; and

FIGS. 3-11 are cross-sectional views of a method of forming a semiconductor structure at various stages in accordance with some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

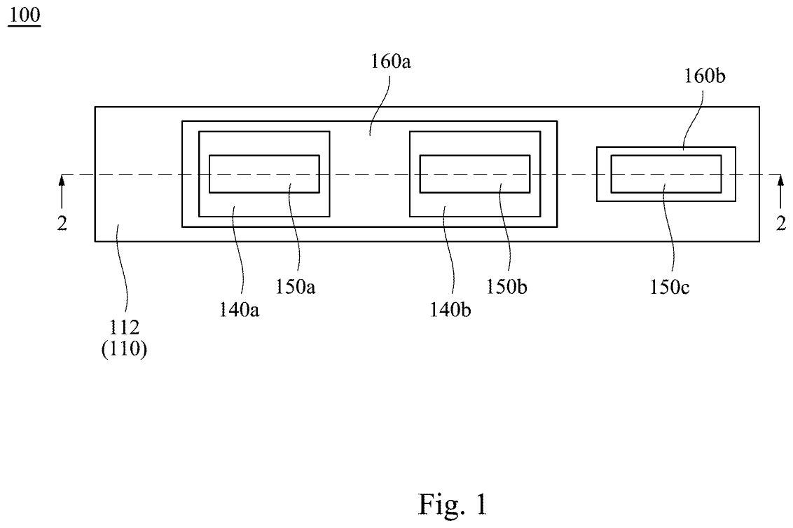

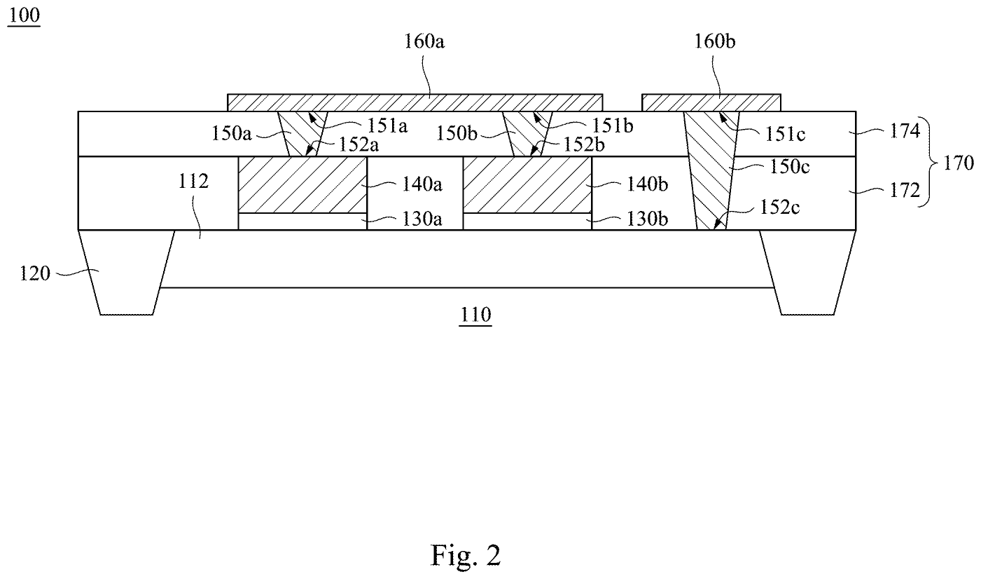

FIG. 1 is a top view of a layout of a semiconductor structure 100 in accordance with some embodiments of the present disclosure, and FIG. 2 is a cross-sectional view of the semiconductor structure 100 taken along line 2-2 of FIG. 1. Referring to FIG. 1 and FIG. 2, the semiconductor structure 100 includes a substrate 110, a shallow trench isolation (STI) structure 120, a first gate structure 140a, a second gate structure 140b, a first contact 150a, and a second contact 150b. The substrate 110 has an active region 112. The STI structure 120 is disposed in the substrate 110 and adjacent to the active region 112. The first gate structure 140a and the second gate structure 140b are disposed on the active region 112. The first contact 150a and the second contact 150b are respectively disposed on the first gate structure 140a and the second gate structure 140b. In the present embodiment, a vertical projection region of the first gate structure 140a on the substrate 110 and a vertical projection region of the second gate structure 140b on the substrate 110 are spaced apart from the STI structure 120. In other words, the first gate structure 140a and the second gate structure 140b are not in contact with the STI structure 120. As a result of such a configuration, corner rounding effect on an interface of the first gate structure 140a and the active region 112 and an interface of the second gate structure 140b and the active region 112 can be avoided, and thus the stability and the performance of the semiconductor structure 100 can be improved.

The semiconductor structure 100 further includes a first gate dielectric layer 130a and a second gate dielectric layer 130b. The first gate dielectric layer 130a is disposed between the first gate structure 140a and the active region 112, while the second gate dielectric layer 130b is disposed between the second gate structure 140b and the active region 112. In the present embodiment, the first gate dielectric layer 130a is spaced apart from the STI structure 120, and the second gate dielectric layer 130b is spaced apart from the STI structure 120 as well. In greater details, a bottom surface of the first gate dielectric layer 130a and a bottom surface of the second gate dielectric layer 130b are spaced apart from a top surface of the STI structure 120. In other words, a vertical projection region of the first gate dielectric layer 130a on the substrate 110 and a vertical projection region of the second gate dielectric layer 130b on the substrate 110 are spaced apart from the STI structure 120. Stated differently, the first gate dielectric layer 130a and the second gate dielectric layer 130b are not in contact with the STI structure 120. Accordingly, the corner rounding effect can be avoided.

The semiconductor structure 100 further includes a third contact 150c on the active region 112. The second contact 150b is disposed between the first contact 150a and the third contact 150c. In some embodiments, a top surface 151a of the first contact 150a, a top surface 151b of the second contact 150b, and a top surface 151c of the third contact 150c are substantially at same horizontal level. In other words, the top surface 151c of the third contact 150c is substantially coplanar with the top surface 151a of the first contact 150a and the top surface 151b of the second contact 150b. In some embodiments, a bottom surface 152a of the first contact 150a and a bottom surface 152b of the second contact 150b are higher than a bottom surface 152c of the third contact 150c. For example, the bottom surface 152a of the first contact 150a and the bottom surface 152b of the second contact 150b are at same horizontal level, and either the bottom surface 152a of the first contact 150a or the bottom surface 152b of the second contact 150b is higher than the bottom surface 152c of the third contact 150c.

The semiconductor structure 100 further includes an electrode plate 160a extending from the first contact 150a to the second contact 150b, and an electrode plate 160b on the third contact 150c. In some embodiments, the electrode plate 160a and the electrode plate 160b is disposed at same horizontal level.

The semiconductor structure 100 further includes a dielectric layer 170 above the active region 112. In greater detail, the dielectric layer 170 includes a first dielectric layer 172 and a second dielectric layer 174 above the first dielectric layer 172. The first dielectric layer 172 surrounds the first gate structure 140a, the second gate structure 140b, and a portion of the third contact 150c, while the second dielectric layer 174 surrounds the first contact 150a, the second contact 150b, and the other portions of the third contact 150c.

In present embodiments, the first contact 150a, the first gate structure 140a, the first gate dielectric layer 130a and a portion of the underlying active region 112 may be referred as a first fuse structure. Further, the second contact 150b, the second gate structure 140b, the second gate dielectric layer 130b and a portion of the underlying active region 112 may be referred as a second fuse structure. The first fuse structure and the second fuse structure may be electrically connected in parallel. A first voltage may be applied to the fuse structures (e.g., the first fuse structure and the second fuse structure) through the electrode plate 160a on the first contact 150a and the second contact 150b, and a second voltage may be applied to the third contact 150c through the electrode plate 160b on the third contact 150c, in which the first voltage is different from the second voltage. The structure of the first fuse structure and the second fuse structure is beneficial to accumulate the voltage and thus provide a stable breakdown on the first gate dielectric layer 130a and the second gate dielectric layer 130b. As such, the low resistance can be achieved.

In some embodiments, the active region 112 may include N-type dopants, such as arsenic (As), antimony (Sb), phosphorous (P), or other N-type materials. The STI structure 120 may be made of silicon oxide, silicon nitride or a silicon oxynitride, or other suitable materials. The first gate dielectric layer 130a and the second gate dielectric layer 130b may be made of silicon oxide, titanium nitride, silicon nitride, or a high-k dielectric material, other suitable dielectric material, and/or combinations thereof. The first gate structure 140a and the second gate structure 140b may be made of polysilicon or other suitable conductive material. In some embodiments, the first gate structure 140a and the second gate structure 140b are made of same materials. The first contact 150a, the second contact 150b and the third contact 150c may be made of tungsten, copper silicide or other suitable conductive material. In some embodiments, the first contact 150a, the second contact 150b and the third contact 150c are made of same materials. The first dielectric layer 172 and the second dielectric layer 174 may be made of silicon oxide, silicon nitride or a silicon oxynitride, or other suitable materials. In some embodiments, the first dielectric layer 172 and the second dielectric layer 174 are made of same materials.

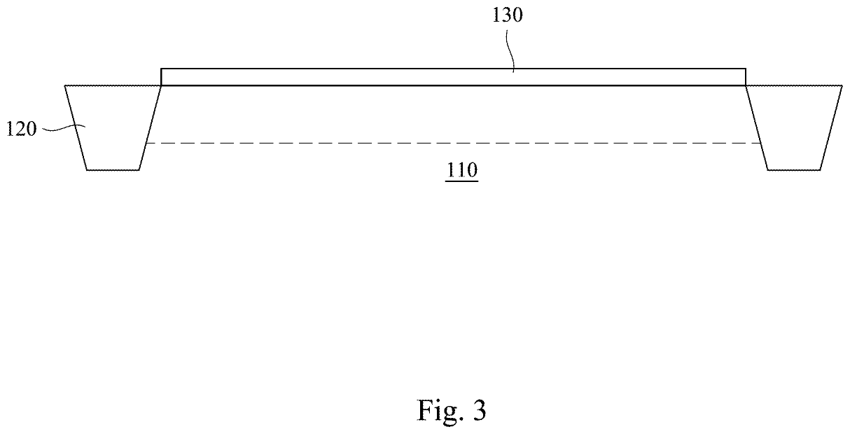

FIGS. 3-11 are cross-sectional views of a method of forming the semiconductor structure 100 of FIG. 2 at various stages in accordance with some embodiments of the present disclosure.

Referring to FIG. 3, the STI structure 120 is formed in the substrate 110. Then, a pad layer 130 is formed over the substrate 110. In some embodiments, the pad layer 130 is a pad oxide layer, and the pad layer 130 is made of silicon oxide or other suitable materials.

In some embodiments, the substrate 110 is a silicon substrate. In some embodiments, the STI structure 120 may be formed by physical vapor deposition (PVD), chemical vapor deposition (CVD), or the like. The pad layer 130 may be formed by CVD, atomic layer deposition (ALD), physical vapor deposition (PVD), thermal oxidation, or other suitable methods.

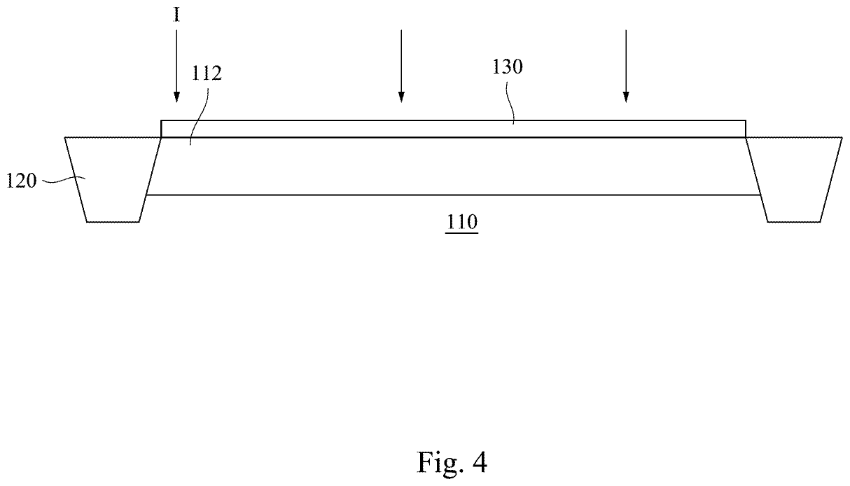

Referring to FIG. 4, an implant process I is performed on the substrate 110 such that the active region 112 is formed adjacent to the STI structure 120. The pad layer 130 is in contact with 112 of the substrate 110. In some embodiments, the substrate 110 is doped by controlling dopants of ion implantation, followed by an annealing process to activate the implanted dopants. For example, the dopants may include N-type dopants, such as arsenic (As), antimony (Sb), phosphorous (P), or other N-type materials.

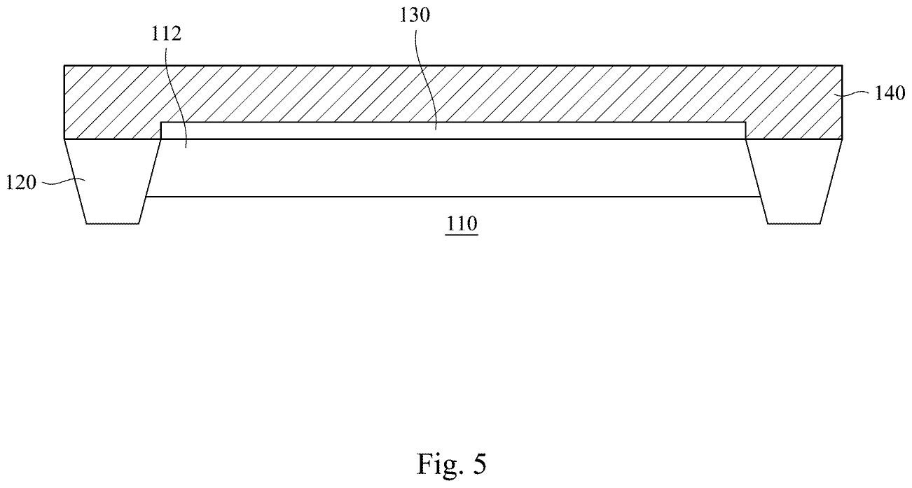

Referring to FIG. 5, a conductive layer 140 is formed over the substrate 110. In greater details, the conductive layer 140 is formed over the pad layer 130. The conductive layer 140 may be made of polysilicon or other suitable conductive materials.

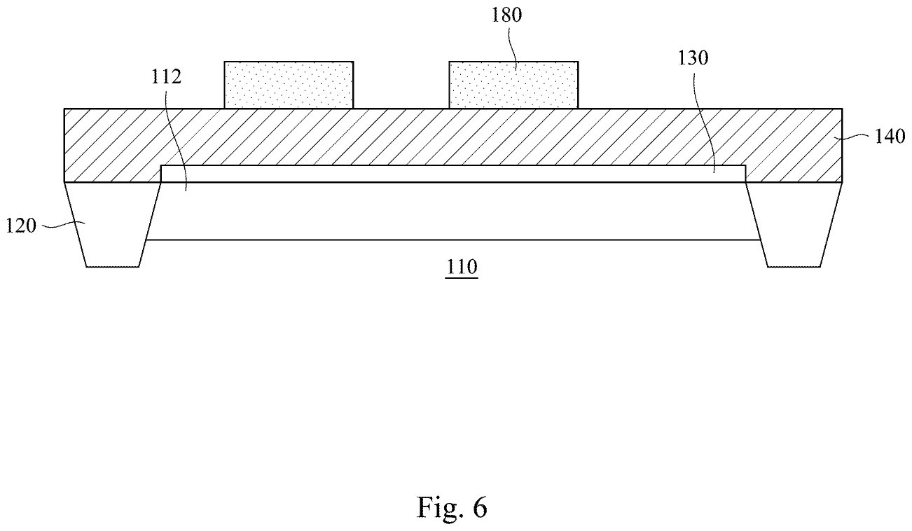

Referring to FIG. 6, a patterned photoresist layer 180 is formed over the conductive layer 140. In greater details, the patterned photoresist layer 180 is formed by forming a photoresist layer over the conductive layer 140 and pattering the photoresist layer into the patterned photoresist layer 180 by using suitable photolithography techniques.

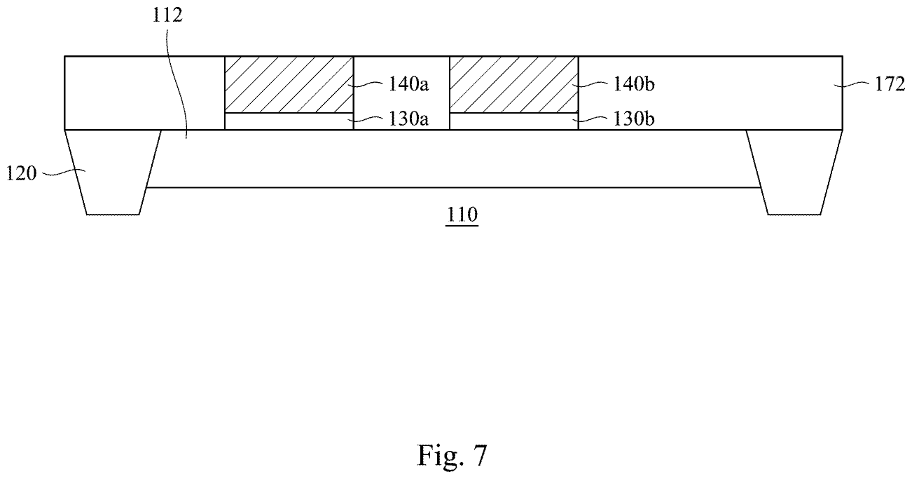

Referring to FIG. 6 and FIG. 7, the conductive layer 140 is etched to form the first gate structure 140a and the second gate structure 140b using the patterned photoresist layer 180 as an etch mask. Further, the pad layer 130 is etched to form the first gate dielectric layer 130a and the second gate dielectric layer 130b using the patterned photoresist layer 180 as the etch mask. In other words, the first gate dielectric layer 130a, the second gate dielectric layer 130b, the first gate structure 140a and the second gate structure 140b are formed by using one etching process.

In some embodiments, the first gate structure 140a and the second gate structure 140b are formed on the active region 112 such that a vertical projection region of the first gate structure 140a on the substrate 110 and a vertical projection region of the second gate structure 140b on the substrate 110 are spaced apart from the STI structure 120. In other words, the first gate structure 140a and the second gate structure 140b are not in contact with the STI structure 120. In some embodiments, the first gate dielectric layer 130a and the second gate dielectric layer 130b are formed on the substrate 110 such that a vertical projection region of the first gate dielectric layer 130a on the substrate 110 and a vertical projection region of the second gate dielectric layer 130b on the substrate 110 are spaced apart from the STI structure 120. In other words, the first gate dielectric layer 130a and the second gate dielectric layer 130b do not overlap the STI structure 120.

In some embodiments, a thickness of the first gate dielectric layer 130a and a thickness of the second gate dielectric layer 130b may be in a range from 20 angstrom (Å) to 30 angstrom (Å). As such, the stable breakdown on the first gate dielectric layer 130a and the second gate dielectric layer 130b can be achieved.

After the first gate structure 140a and the second gate structure 140b are formed, the patterned photoresist layer 180 is removed. In some embodiments, removing the patterned photoresist layer 180 may be performed by using a photoresist strip process, such as an ashing process, and etching process, or other suitable processes.

Thereafter, the first dielectric layer 172 is formed over the substrate 110. In other words, the first dielectric layer 172 surrounds the first gate dielectric layer 130a, the second gate dielectric layer 130b, the first gate structure 140a, and the second gate structure 140b. In some embodiments, the first dielectric layer 172 may be formed by chemical vapor deposition (CVD), atomic layer deposition (ALD), or other suitable methods.

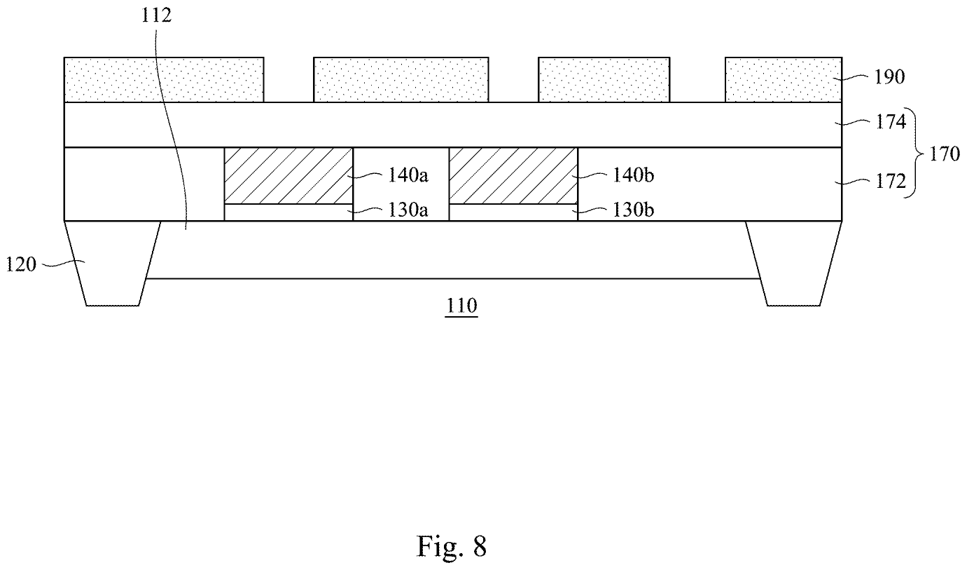

Referring to FIG. 8, after the first dielectric layer 172 is formed, the second dielectric layer 174 is formed over the first dielectric layer 172. In other words, the second dielectric layer 174 covers the first gate structure 140a and the second gate structure 140b. In some embodiments, the second dielectric layer 174 may be formed by chemical vapor deposition (CVD), atomic layer deposition (ALD), or other suitable methods.

Thereafter, a patterned photoresist layer 190 is formed over the second dielectric layer 174. In greater details, the patterned photoresist layer 190 is formed by forming a photoresist layer over the second dielectric layer 174 and pattering the photoresist layer into the patterned photoresist layer 190 by using suitable photolithography techniques.

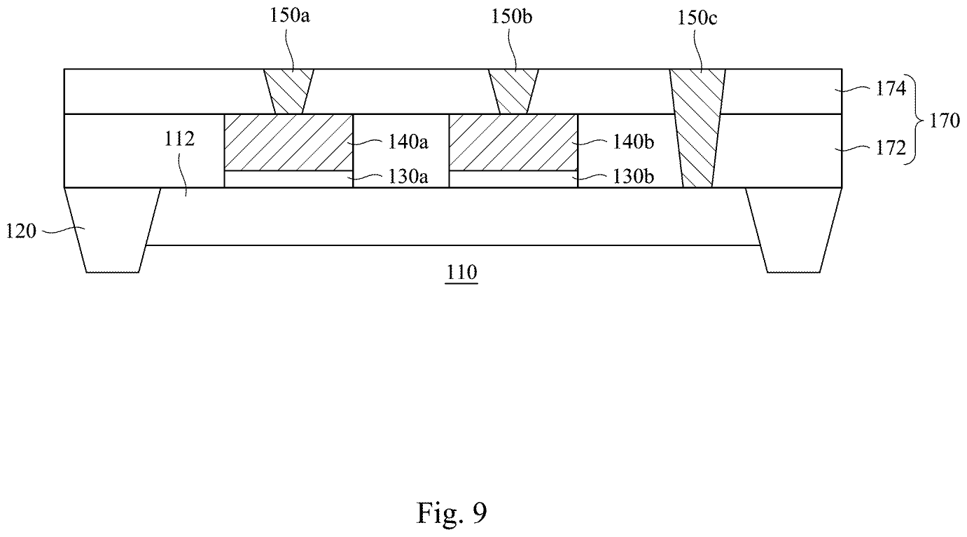

Referring to FIG. 8 and FIG. 9, the second dielectric layer 174 is etched to form openings by using the patterned photoresist layer 190 as an etch mask. Thereafter, conductive materials are filled into the openings to form the first contact 150a, the second contact 150b, and the third contact 150c. In other words, the first contact 150a and the second contact 150b are respectively formed on the first gate structure 140a and the second gate structure 140b, and the third contact 150c is formed on the active region 112.

In some embodiments, forming the first contact 150a and the second contact 150b respectively on the first gate structure 140a and the second gate structure 140b and forming the third contact 150c on the active region 112 are performed by using one deposition process.

After the first contact 150a, the second contact 150b, and the third contact 150c are formed, the patterned photoresist layer 190 is removed. In some embodiments, removing the patterned photoresist layer 190 may be performed by using a photoresist strip process, such as an ashing process, and etching process, or other suitable processes.

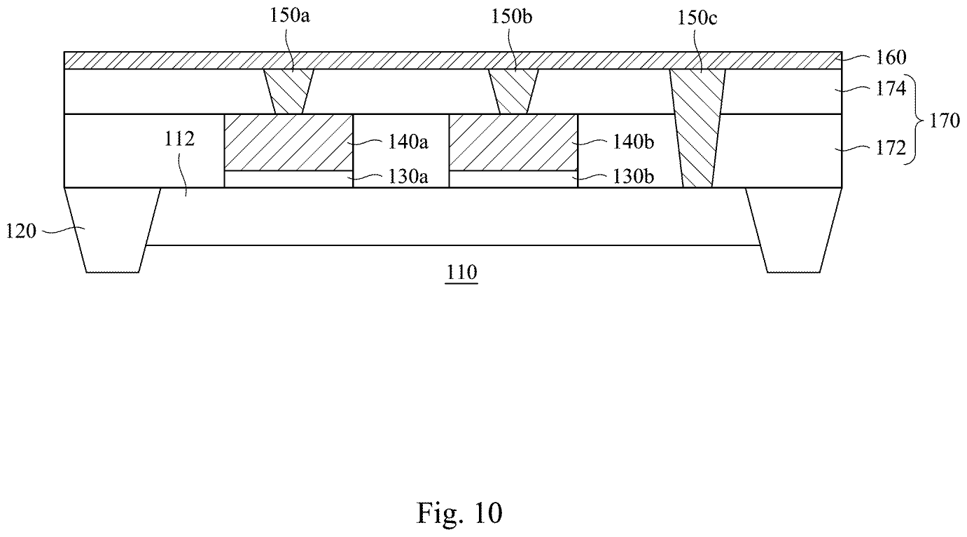

Referring to FIG. 10, a conductive layer 160 is formed over the second dielectric layer 174. In greater details, the conductive layer 160 covers the first contact 150a, the second contact 150b, and the third contact 150c. The conductive layer 160 may be made of polysilicon, metals, or other suitable conductive material.

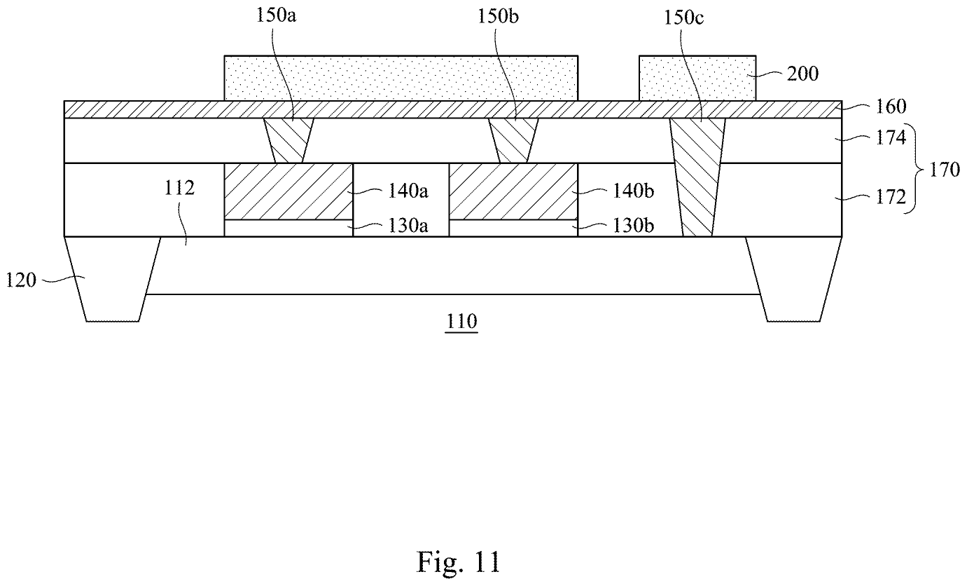

Referring to FIG. 11, a patterned photoresist layer 200 is formed over the conductive layer 160. In greater details, the patterned photoresist layer 200 is formed by forming a photoresist layer over the conductive layer 160 and pattering the photoresist layer into the patterned photoresist layer 200 by using suitable photolithography techniques.

Referring back to FIG. 2, after patterned photoresist layer 200 (see FIG. 11) is formed, the conductive layer 160 (see FIG. 11) is etched to form the electrode plate 160a and the electrode plate 160b using the patterned photoresist layer 200 (see FIG. 11) as an etch mask. In other words, the electrode plate 160a extends from the first contact 150a to the second contact 150b. Further, the electrode plate 160b is disposed on the third contact 150c. After the electrode plate 160a and the electrode plate 160b are formed, the patterned photoresist layer 200 (see FIG. 11) is removed. In some embodiments, removing the patterned photoresist layer 200 (see FIG. 11) may be performed by using a photoresist strip process, such as an ashing process, and etching process, or other suitable processes. As a result, the semiconductor structure 100 as shown in FIG. 2 can be obtained. In some embodiments, forming the electrode plate 160a extending from the first contact 150a and the second contact 150b and forming the electrode plate 160b on the third contact 150c are performed by using one deposition process.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

1. A semiconductor structure, comprising:
a substrate having an active region;
a shallow trench isolation (STI) structure in the substrate and adjacent to the active region;
a first gate structure and a second gate structure on the active region, wherein a vertical projection region of the first gate structure on the substrate and a vertical projection region of the second gate structure on the substrate are spaced apart from the STI structure, and no conductive material is between the first gate structure and the second gate structure; and
a first contact and a second contact respectively on the first gate structure and the second gate structure.

2. The semiconductor structure of claim 1, further comprising:
a third contact on the active region.

3. The semiconductor structure of claim 2, further comprising:
an electrode plate on the third contact.

4. The semiconductor structure of claim 2, wherein a top surface of the first contact, a top surface of a second contact, and a top surface of the third contact are at same horizontal level.

5. The semiconductor structure of claim 2, wherein a bottom surface of the first contact and a bottom surface of a second contact are higher than a bottom surface of the third contact.

6. The semiconductor structure of claim 2, wherein the first contact, the second contact, and third contact are made of same materials.

7. The semiconductor structure of claim 1, further comprising:
an electrode plate extending from the first contact to the second contact.

8. The semiconductor structure of claim 1, further comprising:
a first gate dielectric layer between the first gate structure and the active region; and
a second gate dielectric layer between the second gate structure and the active region.

9. The semiconductor structure of claim 8, wherein the first gate dielectric layer and second gate dielectric layer are spaced apart from the STI structure.

10. The semiconductor structure of claim 1, wherein the active region comprises N-type dopants.

11. A method of forming a semiconductor structure, comprising:
forming a shallow trench isolation (STI) structure in a substrate;
forming an active region adjacent to the STI structure;
forming a first gate structure and a second gate structure on the active region such that a vertical projection region of the first gate structure on the substrate and a vertical projection region of the second gate structure on the substrate are spaced apart from the STI structure, and no conductive material is between the first gate structure and the second gate structure; and
forming a first contact and a second contact respectively on the first gate structure and the second gate structure.

12. The method of forming the semiconductor structure of claim 11, wherein forming the active region comprises performing an implant process on the substrate.

13. The method of forming the semiconductor structure of claim 11, further comprising:
forming a third contact on the active region after forming the first gate structure and the second gate structure on the active region.

14. The method of forming the semiconductor structure of claim 13, wherein forming the first contact and the second contact respectively on the first gate structure and the second gate structure and forming the third contact on the active region are performed by using one deposition process.

15. The method of forming the semiconductor structure of claim 13, further comprising:
forming an electrode plate on the third contact.

16. The method of forming the semiconductor structure of claim 11, further comprising:
forming an electrode plate that extends form the first contact to the second contact.
